(19) United States
(12) Patent Application Publication
(10) Pub. No.: US 2026/0177600 A1
(43) Pub. Date: Jun. 25, 2026

(54) MEASURING DEVICE FOR DETECTING MEASUREMENT SIGNALS CAUSED BY A CABLE FAULT

(71) Applicant: BAUR GmbH, Sulz (AT)

(72) Inventor: Manfred BAWART, Sulz (AT)

(73) Assignee: BAUR GmbH, Sulz (AT)

(21) Appl. No.: 19/422,787

(22) Filed: Dec. 17, 2025

(30) Foreign Application Priority Data
Dec. 20, 2024 (AT) A185/2024

(51) Int. Cl. G01R 31/08; G01R 31/52

(52) U.S. Cl. CPC G01R 31/083; G01R 31/52

(57) ABSTRACT

A measuring device (1) for detecting measurement signals (4) caused by a cable fault (2) and/or jacket fault (3) in the vicinity of the cable (5) is provided. The measuring device (1) includes at least two electrodes (6) which are designed to pick up the measurement signals (4), preferably directly in the ground (7), and the measuring device (1) is designed to perform the following functions: a) receiving a first measurement signal (4a), preferably picked up by the at least two electrodes (6), and b) generating a synchronization signal (8) that is synchronous with the first measurement signal (4a) in terms of time and/or phase, and c) evaluating a second measurement signal (4b) and/or subsequent measurement signal (4c) picked up by the electrodes (6) synchronously with the synchronization signal (8).

### INCORPORATION BY REFERENCE

This application claims priority from Austrian Patent Application No. A185/2024, filed Dec. 20, 2024, which is incorporated herein by reference as if fully set forth.

### TECHNICAL FIELD

The present invention relates to a measuring device for detecting measurement signals caused by a cable fault and/or jacket fault in the vicinity of the cable, wherein the measuring device comprises at least two electrodes which are designed to pick up the measurement signals, preferably directly in the ground.

### BACKGROUND

Measuring devices are essential for the monitoring and safety of low, medium, and high-voltage networks as well as industrial plants. They detect ground faults, i.e., unwanted connections between a conductor and the ground, thus preventing failures, voltage and energy losses, and fire hazards. To detect faults, the devices usually use current and voltage measurements such as zero current and zero voltage measurements to detect deviations in ground currents and ground voltage.

The current state of the art reveals a measuring device that can detect cable faults.

DE 10 2021 124 432 A1 discloses a measuring device for detecting a ground fault in alow-voltage cable network with an adapter for electrical connection to a low-voltage cable grid. The state of the art therefore requires the provision of radio synchronization and an adapter.

DE 10 2010 035 882 A1 shows a device for locating a ground fault on an underground power supply cable URD. It comprises a device for applying an “alternating voltage of a certain polarity” to the cable and an evaluation device for analyzing the step voltage. The evaluation device determines which of the two probes is closer to the ground fault.

DE 10 2012 017 869 B4 shows a device for reducing interference signals. It comprises a signal input, a signal output, and a correction unit. A signal is present at the input that contains a transmission signal and an interference signal, wherein the transmission signal is a pulsed DC voltage signal. The correction unit automatically determines a correction signal that either imposes itself on the input signal or generates a useful signal that is then provided at the output.

### SUMMARY

The purpose of the invention is to improve a measuring device of the type mentioned and/or a method for detecting measurement signals caused by a cable fault and/or jacket fault in the vicinity of the cable and/or a computer program product in such a way that cable faults can be detected more effectively, in particular by eliminating the need for an additional adapter and/or the supply of an external voltage/signal voltage/pulsed DC voltage and/or access to the station and de-energizing of the cable.

For this purpose, the invention according to claim 1 proposes that the measuring device be designed to perform the following functions:
Receiving a first measurement signal, preferably picked up by the electrodes, and
generating a synchronization signal that is synchronous with the first measurement signal in terms of time and/or phase, and
evaluating a second measurement signal and/or subsequent measurement signal picked up by the electrodes synchronously with the synchronization signal.

The synchronous evaluation of the second measurement signal and/or subsequent measurement signals with the synchronization signal can be understood to mean that the second measurement signal and/or subsequent measurement signals are compared in any way with the synchronization signal with regard to the phase position. It is therefore evaluated whether and/or to what degree the second measurement signal and/or subsequent measurement signals are synchronous with the synchronization signal.

The synchronization system, which is preferably part of the measuring device for generating the synchronization signal, can also be referred to as a time synchronization system and can be designed to generate the synchronization signal.

Furthermore, it can be evaluated to what extent the second measurement signal is synchronous and in the same phase angle and/or polarity as the synchronization signal.

The term “surrounding” describes a broad range of definitions and can therefore also describe the earth gradient area and/or the area on the ground surface along the buried cable.

The measuring device may comprise an ground fault detection device and/or a jacket fault location device.

It may be that the first measurement signal and/or second measurement signal and/or the subsequent measurement signal, preferably all measurement signals, are directly synchronized with the synchronization signal in the measuring device.

Radio synchronization, which involves technically complex synchronization and very short and repeatably stable latency times, is therefore obsolete because the measurement signals can be evaluated or compared directly with the synchronization system in the measuring device as described.

According to the invention, it is envisaged that the first measurement signal can be received by means of at least two electrodes.

In technical terminology, the electrodes are sometimes also referred to as step voltage electrodes, step voltage probes, voltage gradient probes, or ground spikes.

It is conceivable that, as an alternative to the at least two electrodes separated from each other, the measurement signals can also be received by means of an A-frame in which the at least two electrodes are integrated.

It is possible that the measurement signals are received via capacitive electrodes.

As mentioned, the A-frame may have at least two electrodes. If a greater tapping distance is desired, it is also conceivable to connect at least one additional (external) electrode to the A-frame.

The electrodes are designed to pick up measurement signals from a substrate, preferably directly from the ground.

The cable may be a medium-voltage cable, a high-voltage cable, or an extra-high-voltage cable, preferably a low-voltage cable.

The cable is preferably powered by an alternating voltage, so that the signals mentioned here will then essentially be alternating and/or periodic signals.

For use in connection with low-voltage networks, especially with unshielded cables, the measuring device may consist of a ground fault detection device.

The measuring device may comprise a sheath fault locator/jacket fault locator in connection with a medium-voltage network and/or high-voltage network and/or extra-high-voltage network, in particular in the case of shielded cables.

In addition to or as an alternative to the step voltage signal, a magnetic field-based signal may be used to determine the cable position, to determine the axial offset to the cable, and/or as a further method for confirming the cable fault.

In this case, it is possible to determine the magnetic field recording of the cable fault by means of at least one sensor, preferably by means of a magnetic field sensor, Hall sensor, or a search coil, based on an alternating current frequency.

Furthermore, it may also be the case that, when passing the cable fault, the magnetic field around the cable fault is determined by means of one or more one-dimensional and/or two-dimensional and/or three-dimensional sensors.

A suitably designed sensor for detecting at least one component of a magnetic field can be used for at least one of the following:
Magnetic field location with simultaneous route determination (by determining the axial offset to the cable)
Coincidence measurement:

Synchronized step voltage location combined with simultaneous magnetic field location for detecting the fault spot.

For the sake of completeness, it should be noted that the description of this invention, the numbers such as one, two, three, and the like are used, only describe the minimum amount of a feature of the invention. Individual features or components of the measuring device may, of course, also be present in in greater numbers. In this sense, the numeral “one” should be understood to mean “at least one,” etc.

It is therefore conceivable that the at least two electrodes are fixed to the measuring device or can be detached at any time, preferably without being destroyed. It is therefore possible that the at least two electrodes can be replaced in the event of defects and/or other requirements.

It may be that, in addition to the first measurement signal, a second or third or fourth, etc., measurement signal can also be detected.

It may be the case that the approach to the cable fault is continued, starting with a first measurement signal, by detecting several measurement signals, preferably in the direction toward the fault.

When evaluating all measurement signals, a phase comparison of the respective measurement signal, in particular the subsequent measurement signal, may be performed with the synchronization signal.

It may be that additively superimposed voltages impair the measurement or detection of the cable fault and/or jacket fault. Exponentially decaying transient disturbances may occur, caused, for example, by the insertion of at least two electrodes into the ground surface. These transients may be many times higher than the AC voltage to be measured.

The measuring device may be designed to reduce interference signals superimposed additively on a measurement signal when detecting cable faults and/or jacket faults.

The measuring device may have a signal input, a signal output, and/or a correction unit, whereby the input signal (e.g., in the form of the first measuring signal, the second measuring signal, or further measuring signals) is present at the signal input, which is an additive superimposition of a measuring signal with an interference signal, in particular a transient interference signal or a superimposed DC voltage.

The “correction unit” may comprise an electrical circuit which automatically “cleans” the input signal present at the signal input by removing the interference signal.

In particular, the correction unit may comprise an FPGA circuit or a microcontroller circuit, each configured with a correspondingly configured software or hardware that implements the correction algorithms.

A “correction signal” is, in particular, a signal generated by the correction unit that is “subtracted” from the input signal so that, ideally, the additive interference signal is eliminated.

In the ideal case, the correction signal corresponds to the interference signal. In this case, subtraction also includes filtering out the interference signal so that the actual useful signal remains.

Furthermore, the correction unit may have a DC component measurement unit, in particular a median filter, and impose the estimated DC component on the input signal for elimination.

This enables to provide a device for locating jacket faults, which directly implements the above Correction device, so that corrections are made to the measurement signals directly and automatically when a jacket fault and/or cable fault is located.

A circuit design for determining the DC voltage component may be used to avoid measurement errors.

The circuit design can evaluate and compensate and/or correct the DC voltage component automatically and/or simultaneously or with a time delay in relation to the DC interference signal. It is also conceivable that the compensation of the DC voltage component is also trained by a self-learning system.

The user may use a predetermined phase angle profile for evaluation in order to filter out interference noise or interference from other cables and/or metallic lines located in the ground.

A frequency filter makes it possible to suppress interference signals.

Suppressing interference signals can play an important role, especially in the vicinity of photovoltaic systems and/or charging stations for electric vehicles and/or low-frequency AC voltages, for example caused by an electric railway line.

In other words, it may be possible to “filter out” the interference signals by using measurement technology.

Signals that additively superimpose the transmitted signal are considered “interference signals.”

This includes, in particular, transient signals such as those generated when at least two electrodes are inserted into the ground.

It is also conceivable that the frequency filter could be trained by a self-learning system in addition to a manually provided phase angle profile.

In other words, it is conceivable that the frequency filter at least includes an algorithm for machine learning with which it trains its filtering of undesired frequencies.

The measuring device may be designed to evaluate more than a quarter, preferably more than half, preferably ¾, and particularly preferably more than 90% of a full period of the first periodic measurement signal and/or the second periodic measurement signal, preferably of all periodic measurement signals.

It may be possible to arbitrarily set which portion of a phase of a measurement signal is evaluated.

Alternatively or in addition to evaluating the respective measurement signals by means of a phase comparison of the respective sine curves, it may be the case that the evaluation of the respective measurement signals is carried out by means of a mathematical method, preferably by means of an envelope curve analysis or a Fourier transformation.

It may be that the first measurement signal and/or the second measurement signal and/or subsequent measurement signals, preferably all measurement signals, comprise a voltage and/or a current.

The voltage may be a step voltage, also called voltage gradient or earth gradient.

The term “step voltage” describes an electrical voltage that occurs between two ground points that are separated by the distance of an average step.

It is conceivable that the step voltage has a different step distance.

It is conceivable that the distance between the at least two electrodes can also be adjusted differently.

The measurement signal can be a step voltage and is typically found in the proximity of the cable fault, as the potential difference is strongest here.

In the present case, it can be understood that the two points of the step voltage on the ground surface are separated from each other by a distance equal to the step length.

The measuring device may be designed to determine the alternating voltage and/or the frequency of the first measuring signal and/or the second measuring signal, preferably of all measuring signals.

The measuring device may be designed to continue generating the synchronization signal on a continuous bases if the measurement signal is interrupted.

An interruption of the measurement signal may occur, for example, when one of the at least two electrodes is lifted and inserted into the ground at another position along the ground surface.

In this case, the synchronization signal continues to be generated despite the interruption of the measurement signal.

The synchronization signal can be generated by means of automatic frequency control, preferably using a clock signal or an internal frequency counter, and by temporally bridging of the zero ranges.

The term “use of a clock signal” describes a method by which the correct timing of an electrical circuit, preferably a digital circuit, can be ensured.

The measuring device may be designed to synchronize the phase position and/or the frequency and/or the voltage level to the synchronization signal generated by the measuring device while receiving the first measurement signal and/or the second measurement signal and/or the subsequent measurement signals, preferably during all measurement signals.

It may be preferable for the measuring device to be designed to synchronize the synchronization signal with the first measurement signal and/or the second measurement signal and/or the subsequent measurement signal, preferably with all measurement signals, with regard to the phase position and/or the frequency and/or the voltage level, preferably using continuous frequency monitoring and/or automatic frequency tracking.

It may be that automatic resynchronization of the frequency occurs in the event of a frequency drift.

It is possible that the frequency drift can be analyzed over a defined period of time. The period of time can be in the range of seconds and/or minutes and/or a number of periods, preferably between 100 periods and 10,000 periods, particularly preferably between 1,000 periods and 10,000 periods.

It is possible to detect a deviation of the phase angle profile in a range of 10 to 20 degrees, preferably in the range of 5 to 10 degrees.

It is possible to adjust the synchronization according to the current grid frequency using continuous adaptive control.

The term “frequency drift” describes a change in the frequency of a signal used for fault diagnosis or monitoring of cables and electrical systems. A drift can occur, for example, when the frequency of an alternating current or the alternating voltage within a cable changes over time.

It may also be possible for the operator to manually readjust the frequency. It is also conceivable that the frequency readjustment could be trained by a self-learning system.

The measuring device may be designed to detect a polarity reversal between the first and second measurement signals and/or subsequent measurement signals, preferably between all measurement signals.

The term “polarity reversal” describes a change in the sign of a measurement signal. A polarity reversal can therefore mean a change in the signal direction. In this case, the sign may be important for the interpretation of measured values.

The measuring device may be designed to compare a second value of a voltage level of the detected second measurement signal with a first value of a first voltage level of the detected first measurement signal.

The term “voltage level” can be understood, for example, as the maximum of the absolute value of the measured voltage.

In the context of cable or jacket faults, the voltage level results from the voltage distribution in the ground, which can also be referred to as a voltage funnel. In the case of cable faults, the voltage funnel describes the voltage caused by the cable fault, which spreads in the vicinity of the fault and/or along the ground. A higher voltage may be present directly at the cable fault.

The voltage level can be measured using at least two electrodes positioned at a defined distance of approximately 0.5 to 2 meters, preferably 0.8 to 1 meter, from each other.

The voltage level can be measured using the A-frame, in which the defined electrode distance can be in the range of 0.2 to 1.5 meters, preferably in the range of 0.4 to 1.0 meters.

The measuring device may be designed to compare and/or interpret a higher amount of the voltage level of the second measurement signal (or further measurement signal) with the amount of the voltage level of the detected first measurement signal (previous, preferably immediately preceding, measurement signal), preferably taking into account the phase position, to compare and/or interpret that the cable fault is located closer to the at least two electrodes during the measurement of the second measurement signal (further measurement signal) than during the measurement of the first measurement signal (previous, preferably immediately preceding, measurement signal).

It may be that the measuring device is designed to compare and/or interpret a lower amount of the voltage level of the second measurement signal (or further measurement signal) to the amount of the voltage level of the detected first measurement signal (previous, preferably immediately preceding, measurement signal), preferably taking into account the phase position, and/or to interpret that the cable fault is located further away from the at least two electrodes during the measurement of the second measurement signal (further measurement signal) than during the measurement of the first measurement signal (previous, preferably immediately preceding, measurement signal).

In other words, this may mean that, with a lower voltage level of the second measurement signal, the at least two electrodes, in particular the second measurement, are further away from the cable fault than during the first measurement.

It may therefore be the case that, in the present invention, synchronization enables directional detection of the cable fault.

It is conceivable that the direction detection is displayed by means of a direction indicator on a display that can be integrated into the measuring device, in particular the jacket fault locator and/or ground fault detector.

It is also conceivable that the direction detection is indicated by means of an acoustic direction indicator.

The measuring device may have an integrated loudspeaker for providing an acoustic signal. However, an external loudspeaker or headphones may also be connected to the measuring device in order to output an acoustic signal. The signal can also be transmitted to the headphones wirelessly.

It may therefore be necessary to repeat the measurement, i.e., to measure a third measurement signal or a fourth measurement signal, etc., and to compare the respective voltage levels of the respective measurement signals again in order to locate the cable fault.

It may be particularly preferable for the last measurement signal recorded, in particular the second measurement signal and/or the subsequent measurement signals, to be evaluated synchronously with the synchronization signal.

Everything disclosed in the present disclosure in connection with the first measurement signal and the second measurement signal applies analogously to the penultimate measurement signal and the last recorded measurement signal, preferably to all measurement signals.

However, it is also conceivable to transfer the coordinates to a three-dimensional coordinate system, preferably with the aid of GPS coordinates of the individual measurements.

The measuring device may be designed to offer the measured data obtained from the first measurement signal and/or the second measurement signal and/or subsequent measurement signals, preferably all measurement signals, and/or a voltage level and/or a directional indication visually or acoustically.

It is possible to visually and acoustically present the history log of the respective measurements and/or the voltage levels and/or the directional information.

It is therefore conceivable that the measuring device has an integrated screen or an integrated display or an integrated touchscreen that visualizes the measurement data obtained.

As mentioned, it is also conceivable that the direction detection is indicated by means of an acoustic direction indicator.

However, it is also possible that the measuring device has a connection or interface to which an external monitor, tablet, or laptop can be connected. Data transmission can also be wireless.

It is conceivable that the integrated screen of the measuring device displays the respective measurement signals in color and/or black and white.

The measuring device may be designed to determine the coordinates using GPS positioning during the measurement of the first measurement signal and/or second measurement signal and/or subsequent measurement signal, preferably all measurement signals.

It is possible to use predefined GPS coordinates and/or map data and/or cable laying data during the measurement of all measurement signals.

The measuring device may be designed to transfer the coordinates obtained by means of GPS positioning, preferably automatically, to a cartographic system.

A second example according to the invention shows a measuring device for detecting measurement signals caused by a cable fault and/or jacket fault in the vicinity of the cable, preferably according to one of the preceding claims, wherein the measuring device comprises at least two electrodes which are designed to pick up the measurement signals, preferably directly in the area, characterized in that a reference electrode is additionally provided and the measuring device is designed to perform the following functions:
Receiving a reference signal picked up by the reference electrode, and
evaluating a measurement signal and/or subsequent measurement signal picked up by the at least two electrodes synchronously with the reference signal.

It may be that the measuring device can determine the potential difference between at least one of the two electrodes and the reference electrode.

In addition to the invention as a measuring device per se, the invention also relates to a Method for detecting measurement signals caused by a cable fault in the vicinity of the cable, preferably by means of a measuring device, comprising the following steps:
recording a first measurement signal, preferably picked up by at least two electrodes, and
generating a synchronization signal that is temporally synchronous with the first measurement signal, and
evaluating a second measurement signal and/or subsequent measurement signal picked up by the electrodes synchronously with the synchronization signal.

In addition to a second invention in the form of a measuring device per se, the invention relates to a second method for detecting measurement signals caused by a cable fault and/or jacket fault in the vicinity of the cable, preferably using a measuring device comprising the following steps:
Receiving a reference signal picked up by the reference electrode, and
evaluating a measurement signal and/or subsequent measurement signal picked up by the at least two electrodes synchronously with the reference signal.

The reference electrode is designed to pick up the reference signal from a substrate, preferably directly from the ground.

In preferred implementation example, the entire phase of the first measurement signal and/or the second measurement signal may be used. However, it is also conceivable that only parts of a phase of the first measurement signal and/or the second measurement signal are used.

In other words, this may mean that in preferred implementation examples, the negative and positive half-cycles are used.

It is also conceivable that, in an adapted operating principle, the negative or positive half-cycles are used.

It may be that at least one of the steps, preferably all of the steps, can be repeated if a measurement was unsuccessful.

It is also conceivable that the repetition can also serve to verify the respective measurement signal.

Of course, it is also conceivable that after all steps have been completed, preferably after each individual step, in particular in the event of a polarity change or a change of direction, an automatic repetition of the respective step or all steps takes place.

However, it is also conceivable that the user can freely select which step and/or steps of the procedure should be repeated.

It may be that the individual steps of the process are started manually by an operator and/or automatically when the cable fault, in particular a mains frequency step voltage, is detected with the aid of at least two electrodes.

It is preferable that the cable remains in operation during the execution of a procedure according to the present disclosure and/or the fault rectification.

A particular advantage is that the house connections remain connected to the cable during the measurement and therefore do not need to be disconnected, as in many cases disconnection is only possible by entering the houses.

It may be necessary to repeat all the steps to detect each additional measurement signal.

In other words, this may mean that each of the procedure steps is applied to all further measurement signals.

The measuring device may be designed to detect the first measurement signal and/or the second measurement signal, preferably all measurement signals and/or subsequent measurement signals, at a different time and/or in a different place using at least two electrodes.

It is therefore possible that the times at which the first measurement signal and/or the second measurement signal, preferably all measurement signals, are detected differ. It is particularly preferred that the second measurement signal is recorded after the first measurement signal.

It cannot be ruled out that several measurements, i.e., several measurement signals, are necessary to detect the cable fault.

There may be several fault locations on the cable.

It may be advantageous to execute the synchronization signal three times with a phase shift of 120 degrees or two times with 180 degrees in each case.

This allows the evaluation of additional fault signals and their assignment to another phase or fault location.

It is also possible that the location or coordinates at which the first measurement signal and/or the second measurement signal, preferably all measurement signals, are detected differ.

Furthermore, the operator may be able to freely decide at what intervals the respective detections of the first measurement signal and/or the second measurement signal, preferably all measurement signals, are performed.

The step voltage measurements (generally first measurement signal, second measurement signal, further measurement signals) are performed in a longitudinal alignment to the cable, i.e., along the cable. In the vicinity of the fault, the measurement is also performed additionally in the transverse direction to narrow down the fault in all directions.

In addition to the invention itself, the invention also relates to the use of the measuring device according to the invention in a method according to the invention.

Furthermore, the present invention relates to a computer program product comprising commands which, when executed by a computer, cause the computer to perform the following:
Receiving a first measurement signal, preferably picked up by at least two electrodes,
generating a synchronization signal that is temporally synchronous with the first measurement signal, and
   evaluating a second measurement signal and/or subsequent measurement signal picked up by the electrodes synchronously with the synchronization signal.

Furthermore, the present invention relates to a second computer program product according to the invention, comprising instructions which, when the program is executed by a computer, cause the computer to perform the following:
Receiving a reference signal picked up by the reference electrode, and
evaluating a measurement signal and/or subsequent measurement signal picked up by at least two electrodes synchronously with the reference signal.

Furthermore, the present invention relates to a transistor or non-transistor computer-readable storage medium on which the above-described computer program products are stored, or at least one of them.

### BRIEF DESCRIPTION OF THE DRAWINGS

Further features and details of preferred forms of the inventions are explained by way of example in the following description of the figures. They show:

FIG. 1: a representation of a measurement process for cable faults using the measuring device;

FIG. 2: a representation of the measurement process according to FIG. 1;

FIG. 3: a representation of a first illustrative example with an unshielded multicore cable;

FIG. 4: a cross-sectional view A-A of a cable according to FIG. 3;

FIG. 5: a representation of a second illustrative example with a shielded cable;

FIG. 6: a cross-sectional view B-B of a cable according to FIG. 5;

FIG. 7: a representation of measurement processes with synchronization;

FIG. 8: a representation of measurement processes without synchronization;

FIG. 9: a block diagram

FIG. 10: a representation of a measurement signal;

FIG. 11: a detailed representation for evaluating the first measurement process according to FIG. 7.

### DETAILED DESCRIPTION

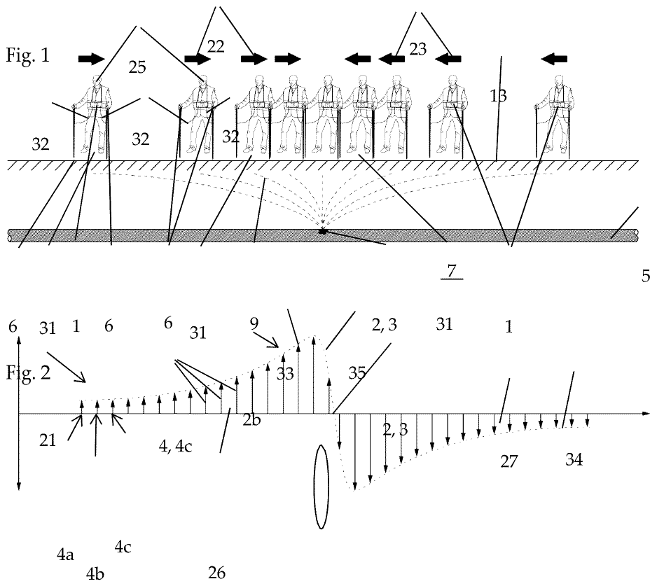

FIG. 1 shows a representation of a measurement process for cable faults 2 and/or jacket faults 3 using the measuring device 1.

FIG. 1 shows an overview of the measurement process, in particular how the user 25 uses the measuring device 1 along the ground surface 13 at various positions 31 with at least two electrodes 6 to locate the cable fault 2 and/or jacket fault 3 of a cable 5.

It is of course conceivable that cable 5 has more than one cable fault 2 and/or jacket fault 3.

The measuring device 1 may comprise a ground fault detection device and/or a jacket fault location device.

It may be that the cable 5 is an unshielded cable or a shielded cable. If the cable 5 is an unshielded cable, it is possible that the measuring device 1 comprises or is a ground fault detection device.

If cable 5 is a shielded cable, it is possible that measuring device 1 comprises or is a jacket fault locator.

FIG. 1 shows that the at least two electrodes 6 are connected to the measuring device 1 via connecting cables 32. It is therefore conceivable that the at least two electrodes 6 are fixed to the measuring device 1 or can be detached at any time, preferably without causing damage.

Preferably, the at least two electrodes 2 are connected to the measuring device via connecting cables 32, whereby these connecting cables 32 can be connected to the measuring device 1 by means of a plug connection.

FIG. 1 illustrates that several measurements and therefore several measurement signals 4 may be necessary to detect a cable fault 2 and/or jacket fault 3.

It is conceivable that each position 31 represents a measurement and thus provides a (first, second, further) measurement signal 4.

As already mentioned above, FIG. 1 shows that the cable 5 is scanned by the user 25 along the ground surface 13 for cable faults 2 and/or jacket faults 3, in particular step voltage signals 20, by means of at least two electrodes 6.

It is conceivable that, upon detection of a measurement signal 4, the measuring device 1 is designed to determine the alternating voltage and/or the frequency of the first measurement signal 4a and/or the second measurement signal 4b and/or the subsequent measurement signals 4c.

For the sake of completeness, it should be noted that in the course of this description of the figures, the term “subsequent measurement signal” can refer to any measurement signal after the second measurement signal.

It should also be noted that the term “measurement signal 4” encompasses the first measurement signal 4a and/or the second measurement signal 4b and/or all measurement signals and/or the subsequent measurement signal 4c.

For the sake of completeness, it should be noted that in the description of this invention, the numbers such as one, two, three, and the like are used, they generally only describe the minimum amount of a feature of the invention.

It is conceivable that as an example of this invention, the measurement signals 4 can be received by means of an A-frame (not shown in the figures) instead of the at least two electrodes 6.

FIG. 1 shows that a first measurement signal 4a is received at a position 31 by means of the at least two electrodes 6.

When inserting the at least two electrodes 6 into the ground 7, transient interference may occur in some cases.

These interference voltages cause an additive superposition to the measurement signal 4, resulting in a disturbed input signal.

It may be provided that the disturbed input signal is improved by filtering or subtracting the disturbance in the form of the additive superposition.

When the first measurement signal 4a is detected, it is conceivable that, in addition to determining the frequency and/or the alternating voltage, a phase comparison of the respective measurement signal 4, in particular the subsequent measurement signal, with the synchronization signal 8 is also performed.

Furthermore, it is possible that a polarity reversal between the first measurement signal 4a and the second measurement signal 4b and/or subsequent measurement signal 4c, preferably between all measurement signals, is also detected.

It is conceivable that the measuring device 1 can display information relating to the measurement, in particular to polarity reversal, in other words, direction detection, preferably via an integrated display and/or an integrated touchscreen, and/or can emit an acoustic signal via a loudspeaker and/or via headphones, thus providing the user 25 with information on when a measurement signal 4 has been detected and/or when the measuring device 1 is ready for the next measurement.

For the second measurement and/or third measurement and/or subsequent measurements, it is conceivable that the at least two electrodes 6 are lifted in order to be able to perform a measurement at another position 31 along the cable on the ground surface 13.

When the at least two electrodes 6 are inserted at another position 31 along the ground surface 13 of the soil 7, it is conceivable that the next measurement will start. Lifting the at least two electrodes 6 may interrupt the measurement signal 4, which is why the last measurement signal 4 recorded remains evaluated synchronously with the synchronization signal 8.

The measuring device 1 may be designed to compare a second value of a voltage level 9 of the detected second measurement signal 4b with a first value of a voltage level 9 of the detected first measurement signal 4a.

It may be that, during a comparison, the measuring device 1 provides the user 25 with information regarding the direction of walk, in particular a first direction 22 and/or a second direction 23. In other words, this describes direction detection, in the context of which it is determined whether the user 25 is moving toward or away from the cable or jacket fault.

If the user 25 is located directly above the cable fault 2 and/or jacket fault 3, it may be that the voltage gradients are balanced out, which is why no measurement signals are measured.

According to the invention, the measuring device 1 generates the synchronization signal 8, which is synchronous with the first measurement signal 4a in terms of time and/or phase, and evaluates a second measurement signal 4b and/or subsequent measurement signal 4c picked up by the at least two electrodes 6 synchronously with the synchronization signal 8.

The measurement process described above is repeated for each measurement signal 4.

The present illustrative example can be used to detect whether or not the user 25 has passed the cable or jacket fault; this is explained in more detail in connection with FIG. 2.

FIG. 2 shows a first diagram 21, in particular a voltage-distance diagram with direction detection, which graphically represents the progress of the measurement process described above.

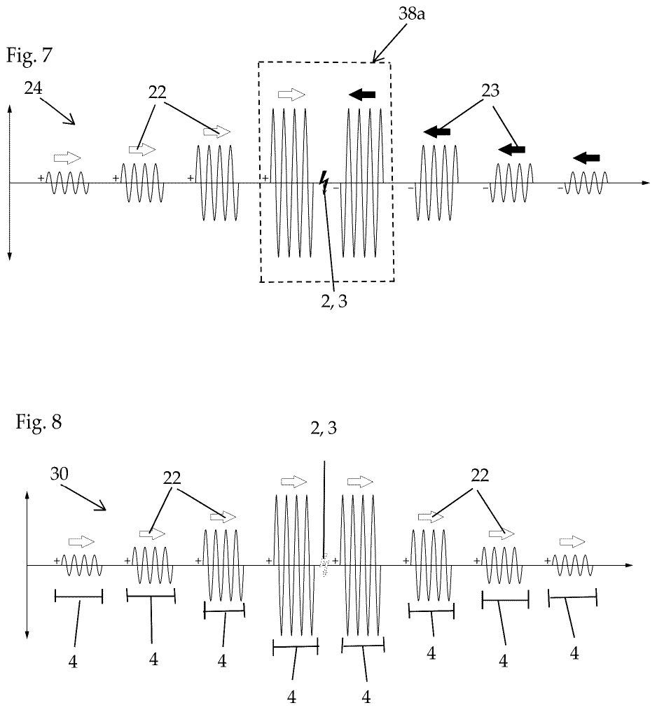

The y-axis of the first diagram 21 shows the voltage level (visualized as an arrow in each case), which is determined from the individual measurement signals 4 (see FIGS. 7 and 11). The x-axis of the first diagram 21 shows the distance.

The sign of the respective arrow (i.e., whether it points up or down) is determined by the polarity of the measurement signal 4 in relation to the synchronization signal 8.

During the first measurement (first measurement signal 4a), the synchronization signal 8 is generated (see FIG. 11), for example in the form of a square-wave voltage in phase with the first measurement signal.

The next recorded measurement signal 4b is compared with the synchronization signal 8 in terms of phase position. In case it is in phase with the synchronization signal, the same polarity is assumed and it is assumed that the cable or jacket fault has not been passed. This is explained in detail in connection with FIGS. 7, 8, and 11.

With the second measurement signal 4b the synchronization signal can be checked and, if necessary, adapted, for example by means of a slight phase angle correction.

In this example, measuring device 1 is designed to synchronize the synchronization signal with the first and second measurement signals 4b and/or subsequent measurement signals 4/4c in terms of phase angle and/or frequency, preferably using continuous frequency monitoring with automatic frequency re-adjusting.

During the next measurement (measurement signal 4c), it is checked again whether the polarity is that of the synchronization signal or not and, if necessary, the synchronization signal is adjusted or re-generated. Furthermore, the increase in voltage magnitude compared to the previous measurement is checked. This is repeated for the subsequent measurements.

The user 25 will move for the subsequent measurements in such a way that the voltage level increases. At a certain point, the cable or jacket fault is passed, causing the polarity of the measurement signal to change (downward arrows in FIG. 2). A signal (e.g., optical or acoustic) is then emitted to indicate that the cable fault has been passed. This is how a direction indicator can be realized.

The user 25 can then determine the exact location of the cable or jacket fault in the vicinity 35 of the fault by making small changes to the electrode position.

In other words, the arrows of the first area 26 along the x-axis of the first diagram 21 show the measurement signals 4, which were received at different positions 31 at different times by means of the at least two electrodes 6, whereby the voltage level at each position 31 has a different height, resulting in a first graph 33 with positive polarity and a second graph 34 with negative polarity.

FIG. 2 accordingly shows a first area 26 with positive polarity and a second area 27 with negative polarity.

The reference symbol 31 generally denotes the positions 31 at which the measurements are performed.

FIG. 2 shows that the first graph 33 and the second graph 34 intersect the x-axis at position 31 of the cable fault 2 and/or the jacket fault 3, because, of course, when the electrodes are positioned exactly symmetrically above the cable or jacket fault, there is no potential difference and therefore no voltage level. This is also the mechanism that is used to determine the precise position of the cable or jacket fault in the vicinity 35.

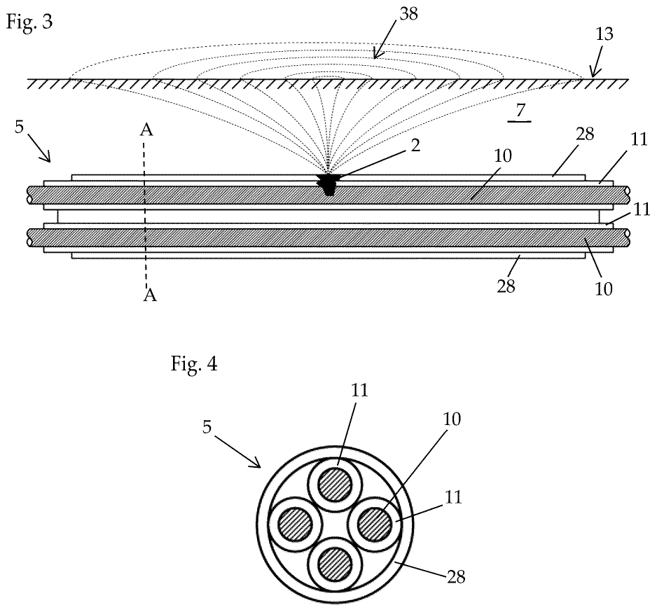

FIG. 3 shows a cable fault 2, which can also be referred to as a ground fault, in cable 5 in a first illustrative example of a low-voltage cable.

FIG. 3 shows that in cable fault 2, the conductor 10 is in contact with the ground 7.

Cable fault 2 in FIG. 3 shows damage to the cable jacket 28 and insulation 11 (conductor insulation).

FIG. 4 shows a cross-sectional view of cable 5 according to FIG. 3 in section A-A.

FIG. 4 shows the conductors 10 with the respective insulation 11 and the cable jacket 28. The cable 5 in FIG. 4 may be a low-voltage cable, preferably an unshielded low-voltage cable.

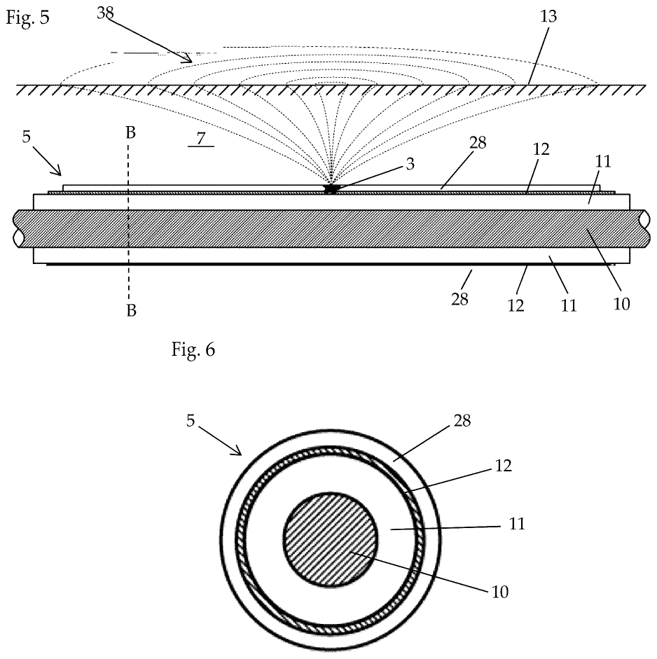

FIG. 5 shows a second illustrative example, namely a jacket fault 3 of cable 5, here a medium-voltage cable or a high-voltage cable with a metallic shield 12. In the case of a jacket fault 3, the cable jacket 28 of cable 5 may be damaged up to the metallic shield 12. Currents induced in the metallic shield 12 also result in a step voltage funnel here.

To detect a jacket fault 3, the measuring device 1 can be a jacket fault locator.

FIG. 6 shows a cross-sectional view of cable 5 according to FIG. 5 in section B-B.

FIG. 6 shows a cable 5, preferably the cable 5 in FIG. 6 can be a medium-voltage cable or high-voltage cable.

The cable 5 in FIG. 6 comprises a conductor 10 surrounded by insulation 11 (here: conductor insulation). The insulation 11 is covered by the metallic shield 12 and the cable jacket 28.

FIG. 7 shows a second diagram 24. The labels on the x-axis and γ-axis of the second diagram 24 correspond to those of the first diagram 21, which is shown in FIG. 2.

FIG. 7 shows a second diagram 24 with a direction indicator, which is illustrated by a first direction 22 and a second direction 23. Each measurement signal 4 indicates, through synchronization and polarity assignment, one of the directions 22, 23 leading to the cable fault 2 or jacket fault 3.

FIG. 7 shows that a distinction is made between positive and negative measurements, in particular positive half-waves 36 and negative half-waves 37 (see FIG. 11).

In this illustrative example, it is important to differentiate between the positive half-waves 36 and the negative half-waves 37 for the direction indication, in particular for the indication of the first direction 22 and/or second direction 23.

FIG. 8 shows a fourth diagram 30. The labels on the x-axis and γ-axis correspond to those in the first diagram 21.

FIG. 8 shows the step voltage signals without synchronization, so that there is no differentiation between positive half-waves 36 and negative half-waves 37 and therefore no direction indication can be made.

FIG. 9 shows a schematic illustration in the form of a block diagram with regard to signal processing.

The (first, second, further) measurement signal 4 detected by the step voltage sensor 14 is first fed to an input amplifier 15 and then to a signal processor 16. The signal processed in this way is fed to the synchronization unit 17 in order to generate or adjust the synchronization signal 8. This is also where the synchronization signal is continuously re-adjusted in case of frequency drift. On the other hand, the processed signal and the synchronization signal 8 are fed to direction detection 18, which detects the direction by synchronously evaluating the measurement signal 4 with the synchronization signal 8 as described above. Depending on the polarity, it can be determined whether or not the cable or jacket fault has been passed. The output 19 is the direction indicator and display of the signal strength and history, so that this information then reaches the user 25.

The signal processing 16 can be carried out as known in the technical state of art.

According to the invention, the step voltage sensor 14 consists of at least two electrodes 6.

In a further working example, the step voltage sensor 14 may be an A-frame.

It is conceivable that the input amplifier 15 can be used for signal amplification and/or as a frequency filter device and/or as an AC coupling device and/or for DC voltage detection and compensation and/or as a delay device and/or comprises at least one of these devices.

The input amplifier 15 may comprise an instrument amplifier and/or an operational amplifier and/or a precision amplifier.

As already mentioned in the description, the frequency filter can be used for interference signal suppression.

Similarly, a predetermined phase angle profile can be used to amplify the measurement signals only by means of the input amplifier 15.

It may be that many measurement signals 4 contain a disturbing DC component that is not relevant for the analysis of AC voltage. For this purpose, DC components are removed so that they are suppressed (DC offset).

It may also be the case that the frequency filter can also suppress the transient interference.

It may be possible to detect and/or evaluate transient disturbances that occur temporarily and decay exponentially, caused, for example, by potential differences due to the time-delayed insertion of at least two electrodes.

A delay device can correct these disturbances in the measured amount.

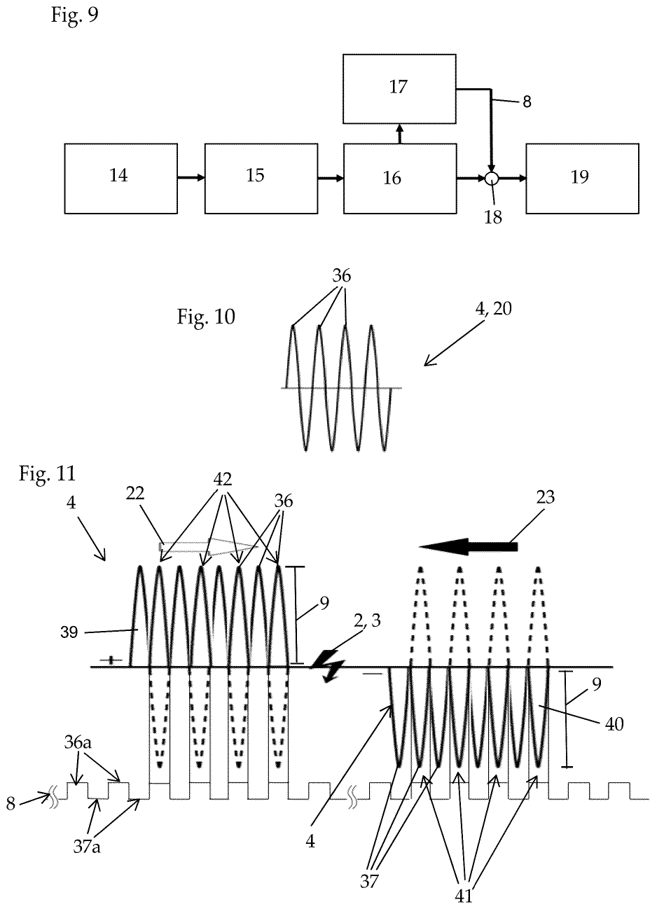

FIG. 10 shows a measurement signal 4. The periodic measurement signal 4 may comprise a step voltage signal 20.

In this example, the measurement signal 4 begins with a positive half-wave 36, followed by the corresponding negative half-wave.

FIG. 11 shows an example of an evaluation of the measurement signals with synchronization before and after the fault location. Synchronization results in the time-accurate assignment and alignment of the polarity of the received measurement signals 4.

FIG. 11 shows a fourth diagram 30. The fourth diagram 30 is a detailed view of area 38a of FIG. 7.

FIG. 11 shows that the synchronization signal 8 also comprises positive synchronization signal half-waves 36a and negative synchronization signal half-waves 37a.

As shown in FIG. 11, signal 8 can be implemented as a square wave signal, but can also be implemented using other signal forms.

FIG. 11 shows an example of how the negative half-waves 36 and/or the positive half-waves 37 of the measurement signal 4, 20 are evaluated based on the synchronization signal 8.

The voltage-time area 39, 40 is or are assigned to a positive half-wave 36 or negative half-wave 37, respectively.

This results in measurement signals 4 with positive half-waves 36 and negative half-waves 37, whereby several, in particular at least two, positive half-waves 36 or negative half-waves 37 can also be referred to as positive voltage-time areas 39 or negative voltage-time areas 40.

It may be preferable to use both half-waves 36, 37 of the alternating voltage.

According to the invention, measurement signals 4 are synchronized with the synchronization signal 8.

For the sake of completeness, it should be mentioned that all half-waves with an even number are defined as positive half-waves 36 and all half-waves with an odd number are defined as negative half-waves 37. It is conceivable that this could be in reverse order.

In order to obtain direction detection, it is conceivable that only one of the half-waves 36, 37, i.e. every second half-wave, either the positive half-waves 36 or the negative half-waves 37, is used.

It is particularly preferable to use both half-waves 36, 37 for direction detection.

FIG. 11 shows that the positive half-waves 36 and the negative half-waves 37 are balanced and assigned in their logic.

FIG. 11 shows that, for direction detection, the voltage-time areas 39, 40 each comprise at least two half-waves 36, 37, each of the half-waves 36, 37 having a defined half-wave width in the range from 0 to 180 degrees.

In FIG. 11, the first half-wave of the signal to the left of the jacket or cable fault 2, 3 is a positive half-wave 36, while the first half-wave of the signal to the right of the jacket or cable fault 2, 3 is a negative half-wave 37.

The synchronization signal 8, which is also shown symbolically, also has positive synchronization signal half-waves 36a and negative synchronization signal half-waves 37a.

The step voltage signal (measurement signal 4) from FIG. 11 is processed with the synchronization signal 8, namely by flipping those half-waves (i.e., assigning them a minus sign) for which a positive synchronization signal half-wave 36a is present at the same time. Those half-waves for which a negative synchronization signal half-wave 37a is present at the same time are not inverted.

This results in generated positive half-waves 42 and generated negative half-waves 41.

As can be seen from FIG. 11, this results in a defined polarity of the signal 4, namely, in the present example, a positive polarity to the left of the cable or jacket fault 2,3 and a negative polarity to the right of the cable or jacket fault 2,3.

On this basis, the first direction 22 or the second direction 23 can be assigned to the measurement signal 4 and output to the user 25.

The measurement can be performed using a half-wave, for example the first half-wave corrected by synchronization.

Advantageously, in other preferred examples, both half-waves of the (first, second, further) measurement signals 4 are used, whereby the voltage-time area 39, 40 and also the measurement signal 4 are doubled.

The generated negative half-wave 41 and/or a generated positive half-wave 42 can be decisive for the detection of the cable fault 2 and/or jacket fault 3.

It is conceivable that the logic of the half-waves, which may be corrected by synchronization, preferably automatically, detects an approximation to the cable fault 2 and/or jacket fault 3 and/or a move away from the cable fault 2 and/or jacket fault 3.

It is also conceivable that false signals caused by grounding band and other metallic conductors can be detected by synchronization, thereby preventing a supposed zero signal from being evaluated as an cable failure.

In summary, the illustrative example described in connection with FIG. 11 determines, by synchronous evaluation of the (second or further) measurement signal with the synchronization signal, whether the respective measurement signal 4 is essentially in phase or out of phase with the synchronization signal 8. In the first case (in phase), the cable or jacket fault has not yet been passed, while in the second case (out of phase), it has.

Of course, other examples are also conceivable, in which, for example, the synchronization signal 8 is generated in antiphase with the first measurement signal 4 and the cable or jacket fault is concluded to have been passed when the synchronization signal 8 is in phase with the second or further measurement signal 4.

### LIST OF REFERENCE SYMBOLS

1 Measuring device
2 Cable fault
3 Jacket fault
4 Measurement signals
4a First measurement signal
4b Second measurement signal
4c Subsequent measurement signal
5 Cable
6 Electrodes
7 Soil
8 Synchronization signal
9 Voltage level
10 Conductor
11 Insulation
12 metallic shield
13 Ground surface
14 Step voltage sensor
15 Input amplifier
16 Signal processing
17 Synchronization
18 Direction detection vector
19 Output device
20 Step voltage signal
21 First diagram
22 First direction
23 Second direction
24 Second diagram
25 User
26 First area
27 Second area
28 Cable jacket
29 Third diagram
30 Fourth diagram
31 Position
32 Connecting cable
33 First graph
34 Second graph
35 vicinity of fault
36 Positive half-wave
36a Positive synchronization signal half-wave
37 Negative half-wave
37a Negative synchronization signal half-wave
38 Step voltage funnel
38a Range
39 Positive voltage time area
40 Negative voltage time area
41 Generated negative half-wave
42 Generated positive half-wave

1. A measuring device (1) for detecting measurement signals (4) caused by a cable fault (2) and/or jacket fault (3) in a vicinity of a cable (5), the measuring device (1) comprising:
at least two electrodes (6) which are designed to pick up the measurement signals (4), and the measuring device (1) is configured to:
receive a first measurement signal (4a), and
generate a synchronization signal (8) that is synchronous with the first measurement signal (4a) in terms of time and/or phase, and
evaluate a second measurement signal (4b) and/or subsequent measurement signals (4c) picked up by the at least two electrodes (6) synchronously with the synchronization signal (8).

2. The measuring device (1) according to claim 1, wherein the measuring device (1) is configured to evaluate more than a quarter of a full period of the first periodic measurement signal (4a) and/or the second periodic measurement signal (4b).

3. (canceled)

4. The measuring device (1) according to claim 1, wherein the measuring device (1) is configured to determine an alternating voltage and/or a frequency of at least one of the first measurement signal (4a), the second measurement signal (4b), or the subsequent measurement signals (4c).

5. The measuring device (1) according to claim 1, wherein the measuring device (1) is configured to to generate the synchronization signal (8) continuously if the measurement signal (4) is interrupted.

6. The measuring device (1) according to claim 1, wherein the measuring device (1) is configured to synchronize the synchronization signal with at least one of the first measuring signal (4a), the second measuring signal (4b), or the subsequent measuring signal (4c).

7. The measuring device (1) according to claim 1, wherein the measuring device (1) is configured to compare a received second value of a voltage level (9) of the detected second measurement signal (4b) with a received first value of a first voltage level (9) of the detected first measurement signal (4a).

8. The measuring device (1) according to claim 1, wherein the measuring device (1) is configured to detect a polarity reversal between the first measurement signal (4a) and the second measurement signal (4b) and/or one of the subsequent measurement signals (4c).

9. The measuring device (1) according to claim 1, wherein the measuring device (1) is configured to compare and/or interpret a higher value of a voltage level (9) of the second measurement signal (4b) to a value of a voltage level (9) of the detected first measurement signal (4a) and/or to interpret that the cable fault (2) and/or the jacket fault (3) is located closer to the at least two electrodes (6) during the measurement of the second measurement signal (4b) than during the measurement of the first measurement signal (4a).

10. The measuring device (1) according to claim 1, wherein the measuring device (1) is configured to output obtained measurement data of the first measurement signal (4a), and/or the second measurement signal (4b), or the subsequent measurement signals (4c).

11. (canceled)

12. (canceled)

13. The measuring device (1) for detecting the measurement signals (4) caused by the cable fault (2) and/or jacket fault (3) in the vicinity of the cable (5), according to claim 1, wherein the measuring device (1) further comprises a reference electrode, and the measuring device is further configured to:
receive a reference signal picked up by the reference electrode, and
evaluate the measurement signal and/or the subsequent measurement signal picked up by the at least two electrodes (6) synchronously with the reference signal.

14. The measuring device (1) according to claim 13, wherein the measuring device is configured to determine a potential difference between the two electrodes (6) and the reference electrode.

15. A method for detecting measurement signals (4) caused by a cable fault (2) and/or jacket fault (3) in a vicinity of a cable (5) the method comprising the following steps:
recording a first measurement signal,
generating a synchronization signal (8) that is temporally synchronous with the first measurement signal (4a), and
evaluating a second measurement signal (4b) and/or subsequent measurement signal picked up by at least two electrodes (6) synchronously with the synchronization signal (8).

16. The method for detecting measurement signals (4) caused by the cable fault (2) and/or jacket fault (3) in the vicinity of the cable (5) according to one of claims 15 to 12, further comprising the following steps:
receiving a reference signal picked up by a reference electrode, and
evaluating the measurement signal and/or the subsequent measurement signal picked up by the at least two electrodes (6) synchronously with the reference signal.

17. The method according to claim 15, wherein the steps are repeated if a measurement was unsuccessful.

18. The method according to claim 15, wherein all of the steps are to be repeated in order to detect each further one of the measurement signals.

19. The method according to claim 15, further comprising providing a measuring device (1) is configured to detect the first measurement signal (4a) and/or the second measurement signal (4b) and/or the subsequent measurement signals (4c).

20. (canceled)

21. A computer program product comprising commands fixed in a tangible storage medium which, when executed by a computer, cause the computer to perform the following:
receiving a first measurement signal (4a),
generating a synchronization signal (8) that is synchronous with the first measurement signal (4a) in terms of time and/or phase, and
evaluating a second measurement signal (4b) and/or subsequent measurement signals (4c) picked up by at least two electrodes (6) in synchronization with the synchronization signal (8).

22. The computer program product according to claim 21, further comprising commands which, when the program is executed by a computer, cause the computer to perform the following:
receiving a reference signal picked up by a reference electrode, and
evaluating the measurement signal and/or the subsequent measurement signals picked up by the at least two electrodes (6) in sync with the reference signal.

23. (canceled)
